(19) United States
(12) Patent Application Publication
(10) Pub. No.: US 2026/0245598 A1
(43) Pub. Date: Aug. 20, 2026

(54) READ-ONLY MEMORY ARRAY FOR REDUCING THE LAYOUT AREAS OF CAPACITORS AND READ-ONLY MEMORY THEREOF

(71) Applicant: Yield Microelectronics Corp., Zhubei City (TW)

(72) Inventors: Yu-Ting HUANG, Chu-pei City (TW); Chi-Pei WU, Chu-pei City (TW)

(73) Assignee: Yield Microelectronics Corp., Zhubei City (TW)

(21) Appl. No.: 19/188,344

(22) Filed: Apr. 24, 2025

(30) Foreign Application Priority Data
Feb. 20, 2025 (TW) 114106213

(51) Int. Cl. G11C 5/06; H10B 20/00

(52) U.S. Cl. CPC G11C 5/063; H10B 20/30

(57) ABSTRACT

The disclosure describes a read-only memory array and a read-only memory thereof. The read-only memory array includes common-source lines, word lines, bit lines, and read-only memories. Each read-only memory includes an N-channel FET, an electronic switch, and a capacitor. The source of the N-channel FET is coupled to the common-source line. The electronic switch is coupled between the drain of the N-channel FET and the bit line. The capacitor is coupled between the gate of the N-channel FET and the word line. The N-channel FET and the capacitor are formed in a P-type semiconductor region. The capacitor includes a first N-type heavily-doped area, a first dielectric block, and an electrode block. The electrode block has a strip portion and finger portions. Each finger portion extends to the first N-type heavily-doped area.

### BACKGROUND OF THE INVENTION

This application claims priority for the TW patent application no. 114106213 filed on 20 February 2025, the content of which is incorporated by reference in its entirely.

### Field of the Invention

The present invention relates to a memory device, particularly to a read-only memory array and a read-only memory thereof.

### Description of the Related Art

The Complementary Metal Oxide Semiconductor (CMOS) technology has been developed as a commonly used process for fabricating Application Specific Integrated Circuits (ASIC). Nowadays, as the computer information products are blooming, flash memories and Electrically Erasable Programmable Read Only Memory (EEPROM) have been widely used in electronic products since the data stored within will not volatilize but can be erased and programmed electrically. In addition, the data will not disappear even after the power is turned off.

Non-volatile memories are programmable and are able to adjust gate voltages of their transistors by storing charges, or to preserve the original gate voltages of transistors by not storing charges. When regarding to erase a non-volatile memory, the charges stored in the non-volatile memory are removed to resume the initial state of the memory, and return to its original gate voltages of the transistors. When the non-volatile memory is programmed, its internal switches will be turned off or turned on. In order to program the non-volatile memory array, a certain voltage and current need to be applied, so that the corresponding switches can be turned on or off. In order to improve the stability, reliability, power consumption, storage density and read speed of the read-only memory, the area of the gate capacitor is usually larger. However, when the area of the gate capacitor becomes larger, the overall resistance becomes higher and the capacitance becomes lower.

To overcome the abovementioned problems, the present invention provides a read-only memory array and a read-only memory thereof, so as to solve the afore-mentioned problems of the prior art.

### SUMMARY OF THE INVENTION

The present invention provides a read-only memory array and a read-only memory thereof, which greatly reduces the layout area of a capacitor and an overall resistance and increases capacitance.

In an embodiment of the present invention, a read-only memory array is provided. The read-only memory array includes a plurality of common-source lines, a plurality of word lines, a plurality of bit lines, and a plurality of read-only memories. The common-source lines, arranged in parallel, include a first common-source line. The word lines are arranged in parallel. The word lines perpendicular to the common-source lines include a first word line. The bit lines are arranged in parallel. The bit lines perpendicular to the word lines include a first bit line. Each read-only memory is coupled to one common-source line, one word line, and one bit line. Each read-only memory includes an N-channel field-effect transistor (FET), an electronic switch, and a capacitor. The source of the N-channel FET is coupled to the first common-source line. The electronic switch is coupled between the drain of the N-channel FET and the first bit line. One terminal of the capacitor is coupled to the gate of the N-channel FET and another terminal of the capacitor is coupled to the first word line. The N-channel FET and the capacitor are formed in a P-type semiconductor region. The capacitor includes a first N-type heavily-doped area, a first dielectric block, and an electrode block. The first N-type heavily-doped area is formed in the P-type semiconductor region and coupled to the first word line. The electrode block is formed on the P-type semiconductor region through the first dielectric block and coupled to the gate of the N-channel FET. The electrode block has a strip portion and finger portions vertical to the first strip portion. One end of each of the finger portions is connected to the strip portion and another end of each of the finger portions extends to the first N-type heavily-doped area.

In an embodiment of the present invention, the capacitor further includes a first N-type well formed in the P-type semiconductor region and the first N-type heavily-doped area formed in the first N-type well.

In an embodiment of the present invention, the N-channel FET includes a second dielectric block, a conductive gate, a second N-type heavily-doped area, and a third N-type heavily-doped area. The second dielectric block is formed on the P-type semiconductor region. The conductive gate is formed on the second dielectric block and coupled to the electrode block. The second N-type heavily-doped area and the third N-type heavily-doped area are formed in the P-type semiconductor region and respectively formed on two opposite sides of the P-type semiconductor region, which is directly arranged under the conductive gate. The second N-type heavily-doped area is coupled to the first common-source line. The third N-type heavily-doped area is coupled to the first bit line through the electronic switch.

In an embodiment of the present invention, the N-channel FET further includes a second N-type well formed in the P-type semiconductor region and the second N-type heavily-doped area is formed in the second N-type well.

In an embodiment of the present invention, when the N-channel FET and the capacitor are selected to perform a programming activity, the P-type semiconductor region is coupled to a grounding voltage, the first word line is coupled to a high voltage, the first common-source line is coupled to the grounding voltage, and the first bit line is electrically floating. The high voltage is greater than the grounding voltage.

In an embodiment of the present invention, when the N-channel FET and the capacitor are not selected to perform a programming activity, the P-type semiconductor region is coupled to a grounding voltage, the first word line is coupled to the grounding voltage, the first common-source line is coupled to the grounding voltage, and the first bit line is electrically floating.

In an embodiment of the present invention, when the N-channel FET and the capacitor are selected to perform an erasing activity, the P-type semiconductor region is coupled to a grounding voltage, the first word line is coupled to the grounding voltage, the first common-source line is coupled to a high voltage, and the first bit line is electrically floating. The high voltage is greater than the grounding voltage.

In an embodiment of the present invention, when the N-channel FET and the capacitor are not selected to perform an erasing activity, the P-type semiconductor region is coupled to a grounding voltage, the first word line is coupled to a middle voltage, the first common-source line is coupled to a high voltage, and the first bit line is electrically floating. The high voltage is greater than the middle voltage and the middle voltage is greater than the grounding voltage.

In an embodiment of the present invention, the strip portion is coupled between the gate of the N-channel FET and the finger portion.

In an embodiment of the present invention, the P-type semiconductor region is a semiconductor substrate or an epitaxial layer formed on a semiconductor substrate.

In an embodiment of the present invention, a read-only memory includes an N-channel field-effect transistor (FET), an electronic switch and a capacitor. The source of the N-channel FET is coupled to a common-source line. The electronic switch is coupled between the drain of the N-channel FET and a bit line. One terminal of the capacitor is coupled to the gate of the N-channel FET and another terminal of the capacitor is coupled to a word line perpendicular to the bit line and the common-source line. The N-channel FET and the capacitor are formed in a P-type semiconductor region. The capacitor includes a first N-type heavily-doped area, a first dielectric block, and an electrode block. The first N-type heavily-doped area is formed in the P-type semiconductor region and coupled to the word line. The electrode block is formed on the P-type semiconductor region through the first dielectric block and coupled to the gate of the N-channel FET. The electrode block has a strip portion and finger portions vertical to the first strip portion. One end of each of the finger portions is connected to the strip portion and another end of each of the finger portions extends to the first N-type heavily-doped area.

In an embodiment of the present invention, the capacitor further includes a first N-type well formed in the P-type semiconductor region and the first N-type heavily-doped area formed in the first N-type well.

In an embodiment of the present invention, the N-channel FET includes a second dielectric block, a conductive gate, a second N-type heavily-doped area, and a third N-type heavily-doped area. The second dielectric block is formed on the P-type semiconductor region. The conductive gate is formed on the second dielectric block and coupled to the electrode block. The second N-type heavily-doped area and the third N-type heavily-doped area are formed in the P-type semiconductor region and respectively formed on two opposite sides of the P-type semiconductor region, which is directly arranged under the conductive gate. The second N-type heavily-doped area is coupled to the common-source line. The third N-type heavily-doped area is coupled to the bit line through the electronic switch.

In an embodiment of the present invention, the N-channel FET further includes a second N-type well formed in the P-type semiconductor region and the second N-type heavily-doped area is formed in the second N-type well.

In an embodiment of the present invention, when the N-channel FET and the capacitor are selected to perform a programming activity, the P-type semiconductor region is coupled to a grounding voltage, the word line is coupled to a high voltage, the common-source line is coupled to the grounding voltage, and the bit line is electrically floating. The high voltage is greater than the grounding voltage.

In an embodiment of the present invention, when the N-channel FET and the capacitor are not selected to perform a programming activity, the P-type semiconductor region is coupled to a grounding voltage, the word line is coupled to the grounding voltage, the common-source line is coupled to the grounding voltage, and the bit line is electrically floating.

In an embodiment of the present invention, when the N-channel FET and the capacitor are selected to perform an erasing activity, the P-type semiconductor region is coupled to a grounding voltage, the word line is coupled to the grounding voltage, the common-source line is coupled to a high voltage, and the bit line is electrically floating. The high voltage is greater than the grounding voltage.

In an embodiment of the present invention, when the N-channel FET and the capacitor are not selected to perform an erasing activity, the P-type semiconductor region is coupled to a grounding voltage, the word line is coupled to a middle voltage, the common-source line is coupled to a high voltage, and the bit line is electrically floating. The high voltage is greater than the middle voltage and the middle voltage is greater than the grounding voltage.

In an embodiment of the present invention, the strip portion is coupled between the gate of the N-channel FET and the finger portion.

In an embodiment of the present invention, the P-type semiconductor region is a semiconductor substrate or an epitaxial layer formed on a semiconductor substrate.

To sum up, the read-only memory array and the read-only memory thereof employ the electrode block having the smallest area and finger portions that overlap the first dielectric block, so as to obtain the greatest capacitance, thereby greatly reducing the layout area of a capacitor and an overall resistance and optimizing the properties of the memory.

Below, the embodiments are described in detail in cooperation with the drawings to make easily understood the technical contents, characteristics and accomplishments of the present invention.

### BRIEF DESCRIPTION OF THE DRAWINGS

FIG. 1 is a schematic diagram illustrating a read-only memory array according to an embodiment of the present invention;

FIG. 2 is a schematic diagram illustrating the circuit layout of a read-only memory according to an embodiment of the present invention;

FIG. 3 is a cross-sectional view of a read-only memory according to a first embodiment of the present invention; and

FIG. 4 is a cross-sectional view of a read-only memory according to a second embodiment of the present invention.

### DETAILED DESCRIPTION OF THE INVENTION

Reference will now be made in detail to embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatives and modifications will be apparent to those skilled in the art, once informed by the present disclosure.

Unless otherwise specified, some conditional sentences or words, such as “can”, “could”, “might”, or “may”, usually attempt to express what the embodiment in the present invention has, but it can also be interpreted as a feature, element, or step that may not be needed. In other embodiments, these features, elements, or steps may not be required.

Reference throughout this specification to “one embodiment” or “an embodiment” means that a particular feature, structure, or characteristic described in connection with the embodiment is included in at least one embodiment. Thus, the appearances of the phrases "in one embodiment" or “in an embodiment” in various places throughout this specification are not necessarily all referring to the same embodiment.

Certain terms are used throughout the description and the claims to refer to particular components. One skilled in the art appreciates that a component may be referred to using different names. This disclosure does not intend to distinguish between components that differ in name but in function. In the description and in the claims, the term “comprise” is used in an open-ended fashion, and thus should be interpreted to mean “include, but not limited to.” The phrases “be coupled to,” “couples to,” and “coupling to” are intended to encompass any indirect or direct connection. Accordingly, if this disclosure mentions that a first device is coupled with a second device, it means that the first device may be directly or indirectly connected to the second device through electrical connections, wireless communications, optical communications, or other signal connections with/without other intermediate devices or connection means.

The invention is particularly described with the following examples which are only for instance. Those skilled in the art will readily observe that numerous modifications and alterations of the device and method may be made while retaining the teachings of the invention. Accordingly, the following disclosure should be construed as limited only by the metes and bounds of the appended claims. In the whole patent application and the claims, except for clearly described content, the meaning of the articles “a” and “the” includes the meaning of “one or at least one” of the elements or components. Moreover, in the whole patent application and the claims, except that the plurality can be excluded obviously according to the context, the singular articles also contain the description for the plurality of elements or components. In the entire specification and claims, unless the contents clearly specify the meaning of some terms, the meaning of the article “wherein” includes the meaning of the articles “wherein” and “whereon”. The meanings of every term used in the present claims and specification refer to a usual meaning known to one skilled in the art unless the meaning is additionally annotated. Some terms used to describe the invention will be discussed to guide practitioners about the invention. The examples in the present specification do not limit the claimed scope of the invention.

In the following description, a read-only memory array and a read-only memory thereof will be provided, which employ the electrode block having the smallest area and finger portions that overlap the first dielectric block, so as to obtain the greatest capacitance, thereby greatly reducing the layout area of a capacitor and an overall resistance and optimizing the properties of the memory.

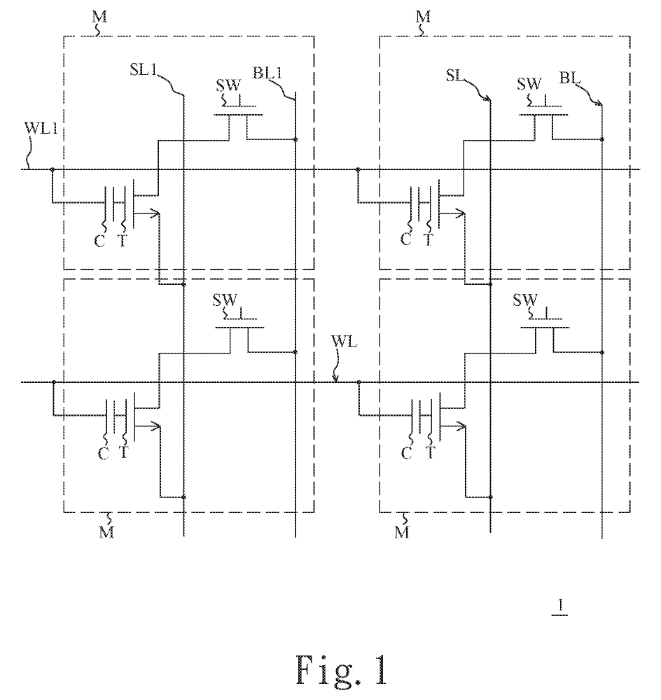

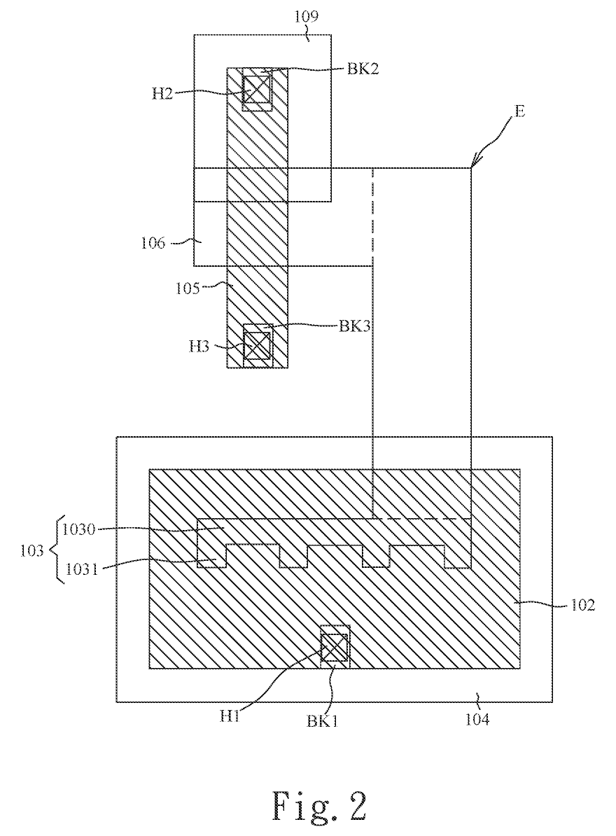

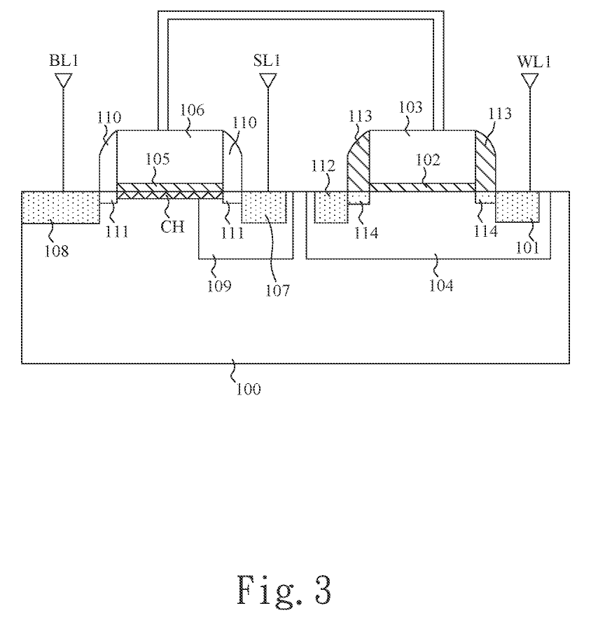

FIG. 1 is a schematic diagram illustrating a read-only memory array according to an embodiment of the present invention. FIG. 2 is a schematic diagram illustrating the circuit layout of a read-only memory according to an embodiment of the present invention. FIG. 3 is a cross-sectional view of a read-only memory according to a first embodiment of the present invention. Referring to FIG. 1, FIG. 2, and FIG. 3, a read-only memory array 1 of the present invention is introduced as follows. The read-only memory array 1 includes a plurality of common-source lines SL arranged in parallel, a plurality of word lines WL arranged in parallel, a plurality of bit lines BL arranged in parallel, and a plurality of read-only memories M. The common-source lines SL include a first common-source line SL1. The word lines WL are perpendicular to the common-source lines SL. The word lines WL include a first word line WL1. The bit lines BL are perpendicular to the word lines WL. The bit lines BL include a first bit line BL1. Each read-only memory M, coupled to one common-source line SL, one word line WL, and one bit line BL, include an N-channel field-effect transistor (FET) T, an electronic switch SW, and a capacitor C. The source of the N-channel FET is coupled to the first common-source line SL1. The electronic switch SW is coupled between the drain of the N-channel FET T and the first bit line BL1. One terminal of the capacitor C is coupled to the gate of the N-channel FET T and another terminal of the capacitor C is coupled to the first word line WL1. The N-channel FET T and the capacitor C are formed in a P-type semiconductor region 100. In the embodiment, the P-type semiconductor region 100 is exemplified by a semiconductor substrate. The capacitor C includes a first N-type heavily-doped area 101, a first dielectric block 102, and an electrode block 103. The first dielectric block 102 is a part of a dielectric layer. The electrode block 103 is a part of an electrode layer E. The dielectric layer, the electrode layer E, and a conductive metal layer are sequentially formed on the P-type semiconductor region 100 from bottom to top. The first N-type heavily-doped area 101 is formed in the P-type semiconductor region 100 and coupled to the first word line WL1. Specifically, a first conduction via H1 overlaps a first conduction block BK1 and penetrates through the first dielectric block 102, such that the first conduction block BK1 is coupled to the first N-type heavily-doped area 101. Since the first conduction block BK1 is a part of the conductive metal layer, the first N-type heavily-doped area 101 is coupled to the first word line WL1 through the first conduction block BK1. The electrode block 103 is formed on the P-type semiconductor region 100 through the first dielectric block 102 and coupled to the gate of the N-channel FET T. The electrode block 103 has a strip portion 1030 and finger portions 1031 vertical to the strip portion 1030. One end of each finger portion 1031 is connected with the strip portion 1030 and another end of each finger portion 1031 extends to the first N-type heavily-doped area 101. When the read-only memory M operates based on Fowler-Nordheim tunneling, the edge of the electrode block 103 that overlaps the first dielectric block 102 will generate a capacitance effect. The strip portion 1030 may cooperate with the edge of the finger portions 1031 to form the electrode block 103 with the smallest area and obtain a highest capacitance value, thereby greatly reducing the layout area of a capacitor and optimizing the properties of the memory.

In some embodiments of the present invention, the capacitor C may further include a first N-type well 104 formed in the P-type semiconductor region 100. The first N-type heavily-doped area 101 is formed in the first N-type well 104. The first N-type well 104 is used to improve the voltage-withstanding properties of the capacitor C. The N-channel FET T may include a second dielectric block 105, a conductive gate 106, a second N-type heavily-doped area 107, and a third N-type heavily-doped area 108. The second dielectric block 105 is a part of the dielectric layer. The conductive gate 106 is a part of the electrode layer E. The second dielectric block 105 is formed on the P-type semiconductor region 100. The conductive gate 106 is formed on the second dielectric block 105 and coupled to the electrode block 103. The second N-type heavily-doped area 107 and the third N-type heavily-doped area 108 are formed in the P-type semiconductor region 100 and respectively formed on two opposite sides of the P-type semiconductor region 100, which is directly arranged under the conductive gate 106. The second N-type heavily-doped area 107 is coupled to the first common-source line SL1. The third N-type heavily-doped area 108 is coupled to the first bit line BL1 through the electronic switch SW. Specifically, a second conduction via H2 overlaps a second conduction block BK2 and penetrates through the second dielectric block 105, such that the second conduction block BK2 is coupled to the second N-type heavily-doped area 107. Since the second conduction block BK2 is a part of the conductive metal layer, the second N-type heavily-doped area 107 is coupled to the first common-source line SL1 through the second conduction block BK2. A third conduction via H3 overlaps a third conduction block BK3 and penetrates through the second dielectric block 105, such that the third conduction block BK3 is coupled to the third N-type heavily-doped area 108. Since the third conduction block BK3 is a part of the conductive metal layer, the third N-type heavily-doped area 108 is coupled to the first bit line BL1 through the third conduction block BK3 and the electronic switch SW. In some embodiments of the present invention, the N-channel FET T may further include a second N-type well 109 formed in the P-type semiconductor region 100. The second N-type heavily-doped area 107 is formed in the second N-type well 109. The second N-type well 109 used to improve the voltage withstanding properties of the N-channel FET T.

The third N-type heavily-doped area 108 is used as a drain and the second N-type heavily-doped area 107 is used as a source. The two sidewalls of the conductive gate 106 are respectively provided with two first sidewall spacers 110 that extend to the sidewall of the second dielectric block 105. There are two first N-type lightly-doped drains (LDDs) 111 which are directly respectively formed under the two first sidewall spacers 110. One of the LDDs 111 is formed in the second N-type well 109. When the MOSFET T is turned on, a channel region CH is formed between the N-type LDDs 111.

In order to meet the requirement of fabrication process, the capacitor C may further include a fourth N-type heavily-doped area 112. The fourth N-type heavily-doped area 112 and the first N-type heavily-doped area 101 are respectively formed on two opposite sides of the first N-type well 104 that is directly formed under the electrode block 103. The two sidewalls of the electrode block 103 are respectively provided with two second sidewall spacers 113 that extend to the sidewall of the first dielectric block 102. There are two second N-type lightly-doped drains (LDDs) 114 which are directly respectively formed under the two second sidewall spacers 113.

The operation of the read-only memory M is introduced as follows, including those of programming and erasing activities. The common-source line, the word line, or bit line is electrically floating or coupled to a high voltage, a middle voltage, or a grounding voltage based on the process characteristics. When the electronic switch SW of the read-only memory M is turned on, the data stored in the read-only memory M can be read. When the electronic switch SW of the read-only memory M is turned off, the data stored in the read-only memory M cannot be read.

When the N-channel FET T and the capacitor C are selected to perform a programming activity, the semiconductor region 100 is coupled to a grounding voltage, the first word line WL1 is coupled to a high voltage, the first common-source line SL1 is coupled to the grounding voltage, and the first bit line BL1 is electrically floating. When the N-channel FET T and the capacitor C are not selected to perform a programming activity, the semiconductor region 100 is coupled to the grounding voltage, the first word line WL1 is coupled to the grounding voltage, the first common-source line SL1 is coupled to the grounding voltage, and the first bit line BL1 is electrically floating. When the N-channel FET T and the capacitor C are selected to perform an erasing activity, the semiconductor region 100 is coupled to the grounding voltage, the first word line WL1 is coupled to the grounding voltage, the first common-source line SL1 is coupled to the high voltage, and the first bit line BL1 is electrically floating. When the N-channel FET T and the capacitor C are not selected to perform an erasing activity, the semiconductor region 100 is coupled to the grounding voltage, the first word line WL1 is coupled to the middle voltage, the first common-source SL1 is coupled to the high voltage, and the first bit line BL1 is electrically floating. In the foregoing operation, the high voltage is greater than the middle voltage and the middle voltage is greater than the grounding voltage. When the read-only memory M operates based on Fowler-Nordheim tunneling, the high voltage is equal to the breakdown voltage of an interface between the second N-type well 109 and the semiconductor region 100. The middle voltage is equal to the drain-to-source breakdown voltage of the N-channel FET T minus the threshold voltage of the N-channel FET T. The grounding voltage is zero voltage.

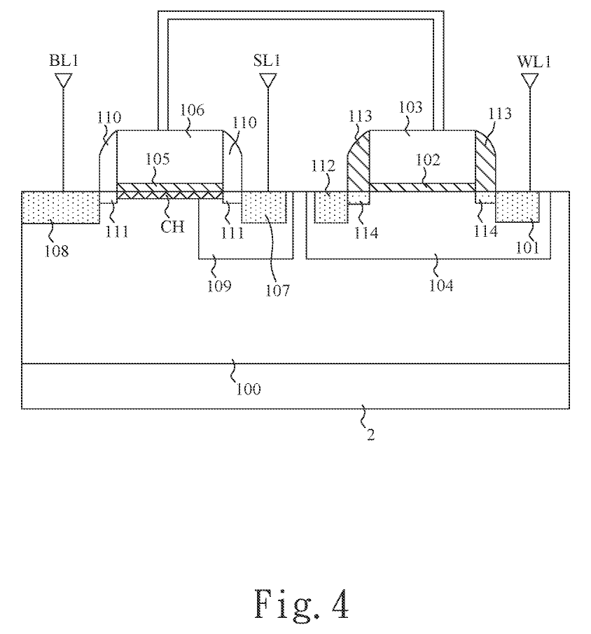

FIG. 4 is a cross-sectional view of a read-only memory according to a second embodiment of the present invention. Please refer to FIG. 4 and FIG. 1. In the embodiment of FIG. 4, the N-channel FET T and the capacitor C may be formed in an epitaxial layer 100 on a semiconductor substrate 2. The epitaxial layer 100 is used as the semiconductor region 100. The other structures of FIG. 4 have been described previously so they will not reiterated.

According to the embodiments provided above, the read-only memory array and the read-only memory employ the electrode block having the smallest area and finger portions that overlap the first dielectric block, so as to obtain the greatest capacitance, thereby greatly reducing the layout area of a capacitor and an overall resistance and optimizing the properties of the memory.

The embodiments described above are only to exemplify the present invention but not to limit the scope of the present invention. Therefore, any equivalent modification or variation according to the shapes, structures, features, or spirit disclosed by the present invention is to be also included within the scope of the present invention.

What is claimed is:

1. A read-only memory array comprising:
a plurality of common-source lines, arranged in parallel, comprising a first common-source line;
a plurality of word lines arranged in parallel, wherein the plurality of word lines perpendicular to the plurality of common-source lines comprise a first word line;
a plurality of bit lines arranged in parallel, wherein the plurality of bit lines perpendicular to the plurality of word line comprises a first bit line; and
a plurality of read-only memories each coupled to one of the plurality of common-source lines, one of the plurality of word lines, and one of the plurality of bit lines, wherein each of the plurality of read-only memories comprises:
an N-channel field-effect transistor (FET) with a source thereof coupled to the first common-source line;
an electronic switch coupled between a drain of the N-channel FET and the first bit line; and
a capacitor with one terminal thereof coupled to a gate of the N-channel FET and another terminal of the capacitor is coupled to the first word line, wherein the N-channel FET and the capacitor are formed in a P-type semiconductor region;
wherein the capacitor comprises:
a first N-type heavily-doped area formed in the P-type semiconductor region and coupled to the first word line;
a first dielectric block; and
an electrode block formed on the P-type semiconductor region through the first dielectric block and coupled to the gate of the N-channel FET, wherein the electrode block has a strip portion and finger portions vertical to the first strip portion, one end of each of the finger portions is connected to the strip portion, and another end of each of the finger portions extends to the first N-type heavily-doped area.

2. The read-only memory array according to claim 1, wherein the capacitor further comprises a first N-type well formed in the P-type semiconductor region and the first N-type heavily-doped area formed in the first N-type well.

3. The read-only memory array according to claim 2, wherein the N-channel FET comprises:
a second dielectric block formed on the P-type semiconductor region;
a conductive gate formed on the second dielectric block and coupled to the electrode block; and
a second N-type heavily-doped area and a third N-type heavily-doped area formed in the P-type semiconductor region and respectively formed on two opposite sides of the P-type semiconductor region, which is directly arranged under the conductive gate, the second N-type heavily-doped area is coupled to the first common-source line, and the third N-type heavily-doped area is coupled to the first bit line through the electronic switch.

4. The read-only memory array according to claim 3, wherein the N-channel FET further comprises a second N-type well formed in the P-type semiconductor region and the second N-type heavily-doped area is formed in the second N-type well.

5. The read-only memory array according to claim 1, wherein when the N-channel FET and the capacitor are selected to perform a programming activity, the P-type semiconductor region is coupled to a grounding voltage, the first word line is coupled to a high voltage, the first common-source line is coupled to the grounding voltage, and the first bit line is electrically floating, wherein the high voltage is greater than the grounding voltage.

6. The read-only memory array according to claim 1, wherein when the N-channel FET and the capacitor are not selected to perform a programming activity, the P-type semiconductor region is coupled to a grounding voltage, the first word line is coupled to the grounding voltage, the first common-source line is coupled to the grounding voltage, and the first bit line is electrically floating.

7. The read-only memory array according to claim 1, wherein when the N-channel FET and the capacitor are selected to perform an erasing activity, the P-type semiconductor region is coupled to a grounding voltage, the first word line is coupled to the grounding voltage, the first common-source line is coupled to a high voltage, and the first bit line is electrically floating, wherein the high voltage is greater than the grounding voltage.

8. The read-only memory array according to claim 1, wherein when the N-channel FET and the capacitor are not selected to perform an erasing activity, the P-type semiconductor region is coupled to a grounding voltage, the first word line is coupled to a middle voltage, the first common-source line is coupled to a high voltage, and the first bit line is electrically floating, wherein the high voltage is greater than the middle voltage and the middle voltage is greater than the grounding voltage.

9. The read-only memory array according to claim 1, wherein the strip portion is coupled between the gate of the N-channel FET and the finger portion.

10. The read-only memory array according to claim 1, wherein the P-type semiconductor region is a semiconductor substrate or an epitaxial layer formed on a semiconductor substrate.

11. A read-only memory comprising:
an N-channel field-effect transistor (FET) with a source thereof coupled to a common-source line;
an electronic switch coupled between a drain of the N-channel FET and a bit line; and
a capacitor with one terminal thereof coupled to a gate of the N-channel FET and another terminal of the capacitor is coupled to a word line perpendicular to the bit line and the common-source line, wherein the N-channel FET and the capacitor are formed in a P-type semiconductor region;
wherein the capacitor comprises:
a first N-type heavily-doped area formed in the P-type semiconductor region and coupled to the word line;
a first dielectric block; and
an electrode block formed on the P-type semiconductor region through the first dielectric block and coupled to the gate of the N-channel FET, wherein the electrode block has a strip portion and finger portions vertical to the first strip portion, one end of each of the finger portions is connected to the strip portion, and another end of each of the finger portions extends to the first N-type heavily-doped area.

12. The read-only memory according to claim 11, wherein the capacitor further comprises a first N-type well formed in the P-type semiconductor region and the first N-type heavily-doped area formed in the first N-type well.

13. The read-only memory according to claim 12, wherein the N-channel FET comprises:
a second dielectric block formed on the P-type semiconductor region;
a conductive gate formed on the second dielectric block and coupled to the electrode block; and
a second N-type heavily-doped area and a third N-type heavily-doped area formed in the P-type semiconductor region and respectively formed on two opposite sides of the P-type semiconductor region, which is directly arranged under the conductive gate, the second N-type heavily-doped area is coupled to the common-source line, and the third N-type heavily-doped area is coupled to the bit line through the electronic switch.

14. The read-only memory according to claim 13, wherein the N-channel FET further comprises a second N-type well formed in the P-type semiconductor region and the second N-type heavily-doped area is formed in the second N-type well.

15. The read-only memory according to claim 11, wherein when the N-channel FET and the capacitor are selected to perform a programming activity, the P-type semiconductor region is coupled to a grounding voltage, the word line is coupled to a high voltage, the common-source line is coupled to the grounding voltage, and the bit line is electrically floating, wherein the high voltage is greater than the grounding voltage.

16. The read-only memory according to claim 11, wherein when the N-channel FET and the capacitor are not selected to perform a programming activity, the P-type semiconductor region is coupled to a grounding voltage, the word line is coupled to the grounding voltage, the common-source line is coupled to the grounding voltage, and the bit line is electrically floating.

17. The read-only memory according to claim 11, wherein when the N-channel FET and the capacitor are selected to perform an erasing activity, the P-type semiconductor region is coupled to a grounding voltage, the word line is coupled to the grounding voltage, the common-source line is coupled to a high voltage, and the bit line is electrically floating, wherein the high voltage is greater than the grounding voltage.

18. The read-only memory according to claim 11, wherein when the N-channel FET and the capacitor are not selected to perform an erasing activity, the P-type semiconductor region is coupled to a grounding voltage, the word line is coupled to a middle voltage, the common-source line is coupled to a high voltage, and the bit line is electrically floating, wherein the high voltage is greater than the middle voltage and the middle voltage is greater than the grounding voltage.

19. The read-only memory according to claim 11, wherein the strip portion is coupled between the gate of the N-channel FET and the finger portion.

20. The read-only memory according to claim 11, wherein the P-type semiconductor region is a semiconductor substrate or an epitaxial layer formed on a semiconductor substrate.
